(19) United States
(12) Patent Application Publication
(10) Pub. No.: US 2006/0249073 A1
(43) Pub. Date: Nov. 9, 2006

(54) Method of heat treatment and heat treatment apparatus

(75) Inventors: Yasushi Asaoka, Hyogo (JP); Tadaaki Kaneko, Hyogo (JP); Nakatsu Sano, Hyogo (JP); Hiroshi Kawai, Saitama (JP); Tomohira Iwazaki, Saitama (JP); Seiji Yamaguchi, Saitama (JP); Hiroyuki Matsumoto, Saitama (JP); Toshiyuki Kouno, Saitama (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: The new industry research organization, Hyogo (JP)

(21) Appl. No.: 10/548,825

(22) PCT Filed: Mar. 10, 2004
(86) PCT No.: PCT/JP04/03152

§ 371 Date: May 10, 2006

(30) Foreign Application Priority Data
Mar. 10, 2003 (JP) 2003-63271
Mar. 10, 2003 (JP) 2003-63275

(51) Int. Cl. C30B 23/00; C30B 25/00; C30B 28/12; C30B 28/14

(52) U.S. Cl. 117/84

(57) ABSTRACT

The present invention is a method suitable for heat treatment, or a heat treatment method for growing single crystal silicon carbide by a liquid phase epitaxial method, wherein a monocrystal silicon carbide substrate as a seed crystal and a polycrystal silicon carbide substrate are piled up, placed inside a closed container, and subjected to high-temperature heat treatment, by which very thin metallic silicon melt layer is interposed between the monocrystal silicon carbide substrate and the polycrystal silicon carbide substrate during heat treatment, and single crystal silicon carbide is liquid-phase epitaxially grown on the monocrystal silicon carbide substrate. The closed container is in advance heated to a temperature exceeding approximately 800° C. in an preheating chamber kept at a pressure of approximately 10⁻⁵ Pa or lower, the closed container is reduced in pressure to approximately 10⁻⁵ Pa or lower, and the container is transported and placed in the heat chamber, which is in advance heated to a prescribed temperature in a range from approximately 1400° C. to 2300° C., in a vacuum at a pressure of approximately 10⁻² Pa or lower or in an inert gas atmosphere at a prescribed reduced pressure, by which the monocrystal silicon carbide substrate and the polycrystal silicon carbide substrate are heated in a short time to a prescribed temperature in a range from approximately 1400° C. to 2300° C. to produce single crystal silicon carbide which is free of fine grain boundaries and approximately 1/cm² or lower in density of micropipe defects on the surface. Further, the present invention is heat treatment equipment used in carrying out the heat treatment method.

### TECHNICAL FIELD

The present invention relates to a heat treatment method used in a liquid phase epitaxial method for growing single crystal silicon carbide and heat treatment equipment suitable for carrying out the method.

### BACKGROUND ART

In conventional heat treatment equipment used in semiconductor production processes, for reducing heat histories of substances to be treated and preventing occurrence of slip, there have been disclosed heat treatment equipment for heat-treating the substances to be treated at a high speed (refer to Patent Document 1: Japanese Published Unexamined Patent Application No. H8-70008) and heat treatment equipment capable of attaining a high vacuum in a short time to perform epitaxial growth at a low pressure (see Patent Document 2: Japanese Published Unexamined Patent Application No. H11-260738) and others.

The conventional heat treatment equipment used in semiconductor production processes were used mainly for epitaxial growth of silicon carbide (hereinafter referred to as SiC). Therefore, the operating temperatures are 950° C. and 800° C. to 900° C. respectively at the high-temperature sections of the heat treatment equipment disclosed in Patent Document 1 and in Patent Document 2, for example.

However, in recent years, single crystal silicon carbide not only excellent in heat resistance and mechanical strength but also resistant to radiation and easy in controlling valence electrons of electrons and electron holes by addition of impurities and also having a wider band gap (for example, about 3.0 eV for 6H-type SiC single crystal and 3.3 eV for 4H-type SiC single crystal) has caught attention as a semiconductor material for next-generation power devices and high-frequency devices, due to its ability to realize high-temperature, high-frequency, voltage resistance and environment resistance which cannot be realized by conventional semiconductor materials such as silicon (hereinafter referred to as Si) or gallium arsenide (hereinafter referred to as GaAs).

Further, hexagonal crystal SiC is close to gallium nitride (hereinafter referred to as GaN) in a lattice constant and is expected to be used as a substrate of GaN.

As disclosed in Patent Document 3: Japanese Published Unexamined Patent Application No. 2001-158695, this type of single crystal SiC is formed by a sublimation and recrystallization method (modified Lely method) in which a seed crystal is fixed and placed on a low-temperature side and powder including Si used as a raw material is placed on a high-temperature side in a crucible and the crucible is then heated to high temperatures ranging from 1450° C. to 2400° C. in an inert atmosphere, by which powder including Si is sublimated to cause recrystallization on the surface of the seed crystal on the low-temperature side, thereby effecting the growth of the single crystal.

Further, as disclosed in Patent Document 4: Japanese Published Unexamined Patent Application No. H11-315000, a SiC single crystal substrate is kept opposed to a plate composed of Si atoms and C atoms in parallel with each other apart from a minute gap, and heat treatment is performed, with a temperature gradient given so that the SiC single crystal substrate can be lower in temperature than the plate in an inert gas atmosphere lower than ambient pressure and also in a SiC saturated vapor atmosphere, by which Si atoms and C atoms are subjected to sublimation and recrystallization inside the minute gap to allow a single crystal to deposit on the SiC single crystal substrate.

In addition, as disclosed in Patent Document 5: Translation of International Application (Kohyo) No. H10-509943, there is a method in which a first epitaxial layer is formed on SiC single crystal by a liquid phase epitaxial method and then a second epitaxial layer is formed on the surface by a chemical vapor deposition (CVD) method to remove micropipe defects.

However, as disclosed in Patent Documents 3 through 5, formation of single crystal SiC by these methods requires heat treatment at high temperatures from 1450° C. to 2400° C., thereby making it difficult to form single crystal SiC by using conventional heat treatment equipment disclosed in Patent Document 1 and Patent Document 2.

Furthermore, for example, in the sublimation and recrystallization method described in Patent Document 3, the crystal grows very fast at several hundred μm/hr, but SiC powder once degrades into Si, SiC₂ and Si₂C and vaporizes on sublimation and then reacts with a part of a crucible. Therefore, changes in temperature result in differences in types of gases arriving at the surface of a seed crystal, which makes it technically very difficult to control a partial pressure of these gases accurately and stoichiometrically. Contamination with impurities may occur easily, and crystal defects, micropipe defects, etc., may also occur easily, due to the influence of distortion resulting from these impurities and heat. There is also a problem that single crystal SiC which is stable in terms of performance and quality is not provided due to development of grain boundaries resulting from much nucleation.

The liquid phase epitaxial methods (hereinafter referred to as LPE method) disclosed in Patent Document 4 and Patent Document 5 are fewer in development of micropipe defects and crystal defects found in the sublimation and recrystallization method and able to provide single crystal SiC better in quality than that produced by the sublimation and recrystallization method. In contrast, since the growth process is restricted by solubility of C in Si melt, the growth speed is very slow, or 10 μm/hr or lower, single crystal SiC is also low-in productivity and liquid phase in the production equipment must be accurately controlled for temperature.

Further, processes are complicated to greatly raise the cost of producing single crystal SiC.

### SUMMARY OF THE INVENTION

The present invention has been made in view of the above problems, an object thereof is to provide a preferable heat treatment method for forming a new material, for example, a next-generation single crystal SiC and preferable heat treatment equipment for carrying out the heat treatment method.

The heat treatment method of the present invention has several features for attaining the above object, which are to be explained as follows. In the present invention, the following major features may be provided whenever necessary solely or in a proper combination. The heat treatment equipment of the present invention is preferable equipment for carrying out the heat treatment method of the present invention.

The heat treatment method of the present invention is a heat treatment method carried out by heat treatment equipment comprising a heat chamber for heating a substance to be treated in a short time at temperatures from approximately 800° C. to 2600° C., preferably from approximately 1200° C. to 2300° C., an anterior chamber connected to the heat chamber and equipped with a transportation means for transporting the substance to be treated to the heat chamber and a preheating chamber connected to the anterior chamber for heating the substance to be treated to a prescribed temperature, wherein after the substance to be treated is heated in advance to a temperature exceeding approximately 800° C. in the preheating chamber kept in a vacuum at a pressure of approximately 10⁻² Pa or lower, preferably approximately 10⁻⁵ Pa or lower, the substance is transported to the heat chamber, which is heated in advance to a prescribed temperature in a range from approximately 800° C. to 2600° C. or preferably from approximately 1200° C. to 2300° C., in a vacuum at a pressure of approximately 10⁻² Pa or lower, preferably approximately 10⁻⁵ Pa or lower or in a rarefied gas atmosphere to which inert gas is introduced after a prior arrival at a vacuum at a pressure of approximately 10⁻² Pa or lower, preferably at a pressure of approximately 10⁻⁵ Pa or lower, thereby heating the substance to be treated in a short time to a prescribed temperature in a range from approximately 800° C. to 2600° C. preferably in a range from approximately 1200° C. to 2300° C.

The heat treatment method of the present invention is able to perform heating in a short time to a prescribed temperature in a range from approximately 800° C. to 2600° C., preferably from approximately 1200° C. to 2300° C., thereby making it possible to create a new material which has not been provided by conventional heat treatment equipment.

The heat treatment method is suitable for a heat treatment method used in a liquid phase epitaxial method for growing single crystal SiC.

To be more specific, the heat treatment method used in the liquid phase epitaxial method for growing single crystal silicon carbide of the present invention is a method wherein a monocrystal silicon carbide substrate as a seed crystal and a polycrystal silicon carbide substrate are piled up, placed inside a closed container and subjected to high-temperature heat treatment, by which a very thin metallic silicon melt layer is interposed between the monocrystal silicon carbide substrate and the polycrystal silicon carbide substrate during the heat treatment and single crystal silicon carbide is liquid-phase-epitaxially grown on the monocrystal silicon carbide substrate.

Then, the heat treatment method used in the liquid phase epitaxial method for growing single crystal silicon carbide of the present invention is a method, wherein the closed container is in advance heated to a temperature exceeding approximately 800° C. in a preheating chamber kept in a high vacuum at a pressure of approximately 10⁻⁵ Pa or lower, and the closed container is reduced in pressure to approximately 10⁻⁵ Pa or lower, the container is transported and placed in the heat chamber, which is in advance heated to a prescribed temperature in a range from approximately 1400° C. to 2300° C., in a vacuum at a pressure of approximately 10⁻² Pa or lower, preferably at a pressure of 10⁻⁵ Pa or lower or in a rarefied gas atmosphere to which some inert gas is introduced after a prior arrival at a high vacuum at a pressure of 10⁻⁵ Pa or lower, by which the monocrystal silicon carbide substrate and the polycrystal silicon carbide substrate are heated in a short time to a prescribed temperature in a range from approximately 1400° C. to 2300° C. to produce single crystal silicon carbide which is free of fine grain boundaries and approximately 1/cm² or lower in density of micropipe defects on the surface.

As explained so far, the above method is able to perform heating in a short time to a prescribed temperature in a range from approximately 1400° C. to 2300° C., thereby making it possible to produce single crystal SiC effectively. In addition, since the thus produced single crystal SiC is free of fine grain boundaries inside crystals grown and approximately 1/cm² or lower in density of micropipe defects on the surface, it can be used in various types of semiconductor devices. In this instance, micropipe defects are also called pin holes, referring to a tubular cavity in a diameter of several μms or lower present along the direction of crystal growth. Any crystal plane of 4H—SiC and 6H—SiC may be used as a monocrystal SiC substrate which is a seed crystal to be used in the invention, but it is preferable to use (0001) Si plane. As a polycrystal SiC substrate, it is preferable to use a plane which is from approximately 5 μm to 10 μm in mean grain size and uniform in grain size. Therefore, there is no particular limit to the crystal structure of polycrystal SiC, and any of 3C—SiC, 4H—SiC and 6H—SiC may be used. However, preferable is 3C—SiC.

Further, according to the present invention, during heat treatment, Si is permeated as wetting into every part of the interface between A monocrystal SiC substrate and a polycrystal SiC substrate by capillarity, thereby forming a very thin metallic Si melt layer. C atoms which flow from the polycrystal SiC substrate are supplied through the Si melt layer to the monocrystal SiC substrate to provide liquid phase epitaxial growth as single crystal SiC on the monocrystal SiC substrate. Therefore, defects which may take place from an initial stage of growth to a completion stage can be prevented. In addition, the present invention makes it possible to greatly reduce a quantity of Si adhered on the monocrystal SiC substrate as a seed crystal after heat treatment and on the polycrystal SiC substrate, which is removed after heat treatment, without the necessity for immersion treatment of the substrates into Si melt, which is required by a conventional method. Further, a very thin metallic Si melt layer is interposed between the monocrystal SiC substrate and the polycrystal SiC substrate during heat treatment, thus making it possible to use only metallic Si necessary for epitaxial growth of single crystal SiC in performing liquid phase epitaxial growth of single crystal SiC. Therefore, the thin Si layer can provide a minimum contacting area with the outside during heat treatment, thereby reducing a possible inclusion of impurities to produce high-purity single crystal SiC.

The heat treatment equipment of the present invention comprises a heat chamber wherein a substance to be treated is heated in a short time to a prescribed temperature in a range from approximately 1200° C. to 2300° C. in a vacuum at a pressure of approximately 10⁻² Pa or lower, preferably approximately 10⁵ Pa or lower, or in a rarefied gas atmosphere to which an inert gas is introduced after a prior arrival at a vacuum at a pressure of approximately 10⁻² Pa or lower, or preferably approximately 10⁻⁵ Pa or lower, an anterior chamber connected to the heat chamber and equipped with a transportation means for transporting the substance to be treated to the heat chamber, and a preheating chamber connected to the anterior chamber for heating in advance the substance to be treated to a temperature exceeding approximately 800° C. in a vacuum at a pressure of approximately 10⁻² Pa or lower, preferably at a pressure of approximately 10⁻⁵ Pa or lower.

The heat treatment equipment of the present invention comprises a high-temperature heating furnace wherein the inside of a vacuum high-temperature furnace is composed of two or more divided tanks, the inside of each of these plurality of tanks is constituted with a main heating tank and a preheating tank, the preheating tank is heated from a room temperature to approximately 800° C. for degassing the gas mainly adsorbed to a sample and the gas contained inside the sample, after completion of the degassing, the sample is smoothly transported to the main heating tank which is in advance discharged of air by heating and vacuum treatment and kept clean and at high temperatures, the main heating tank is constantly heated to a prescribed high temperature in a range from approximately 800° C. to 2600° C. constantly at a pressure of approximately 10⁻³ Pa or lower or in a rarefied gas atmosphere at any given pressure from ambient pressure to approximately 10⁻³ Pa by introduction of some inert gas after a prior arrival at approximately 10⁻³ Pa or lower pressure, the preheating tank has the function of discharging air from ambient pressure for supplying and removing a sample to a pressure level which is the same as that attained by the main heating tank necessary for transporting the sample to or from the main heating tank, and after a preheating of the sample from room temperature to approximately 800° C., a quick transportation to the main heating tank enables to attain a high-temperature and high-purity atmosphere at a prescribed temperature in a range from approximately 800° C. to 2600° C. which is an optimal temperature for treating the sample.

Further, the heat treatment equipment of the present invention is heat treatment equipment having a high-speed and high-temperature heating furnace, wherein a vacuum high-temperature furnace is divided into two tanks or a main heating tank and a preheating tank for rapid heating of a sample, and at the same time for keeping a high-purity atmosphere, the inside of each tank is provided with an individually independent vacuum discharge system or an individually independent gas introduction system and capable of keeping an ambient pressure atmosphere, and the main heating tank and the preheating tank are mutually kept integrated or divided by opening or closing a cut-off valve, the heat treatment equipment having a high temperature heating furnace, wherein the main heating tank is kept at a prescribed high temperature in a range from approximately 800° C. to 2600° C. constantly at a pressure of approximately 10⁻³ Pa or lower during a regular use or in a rarefied gas atmosphere of any given pressure from ambient pressure to approximately 10⁻³ Pa by introduction of some inert gas after a prior arrival at a pressure of approximately 10⁻³ Pa or lower, a cold trap is built in for adsorbing gas which is contained in a sample and released therefrom, and quick-cooling gas circulating equipment is also built in for attaining a quick cooling from a higher temperature after completion of the heating process to room temperature in a state that the preheating tank is kept at a prescribed temperature in a range from room temperature to the temperature below 1000° C.

### BRIEF DESCRIPTION OF THE DRAWINGS

FIG. 1 is a schematic sectional view of one embodiment of the heat treatment equipment used in the liquid phase epitaxial method for growing single crystal SiC according to one embodiment of the present invention.

FIG. 2 is a schematic view of one example of the closed container used in one embodiment of the present invention.

FIG. 3 is a drawing showing the inside of the closed container in one embodiment of the present invention.

FIG. 4 is a drawing showing a state that a substrate is placed on a lower container cup wall in one embodiment of the present invention.

FIG. 5 (a) and FIG. 5 (b) are schematic views showing one example of the reflecting mirror used in one embodiment of the present invention.

FIG. 6 (a) and FIG. 6 (b) are micrographs showing the surface of the growth layer of single crystal SiC obtained by the heat treatment method and the heat treatment equipment according to one embodiment of the present invention. FIG. 6 (a) is a micrograph showing the surface morphology and FIG. 6 (b) is a micrograph showing its cross section thereof.

FIG. 7 (a) and FIG. 7 (b) are AFM (atomic force microscope) pictures of the surface of the surface of single crystal SiC shown in FIG. 6 (a) and FIG. 6 (b). FIG. 7 (a) and FIG. 7 (b) are AFM pictures respectively showing the surface morphology and the section.

FIG. 8 (a), FIG. 8 (b) and FIG. 8 (c) are drawings explaining the step bunching mechanism in the growing course of single crystal SiC obtained by the heat treatment method and the heat treatment equipment according to one embodiment of the present invention.

FIG. 9 (a) and FIG. 9b are sectional views of major parts of the heat treatment equipment in another embodiment of the present invention.

FIG. 10 is a drawing showing the relationship between spectral emissivity and reflectance of W at high temperatures.

FIG. 11 is a drawing showing the wave energy of W in a range from 1800° C. to 2600° C.

FIG. 12 is a drawing showing spectral reflectance characteristics of Au which coats the surface of a metal reflector 5.

FIG. 13 is a sectional view of the major part of the heat treatment equipment according to still another embodiment of the present invention.

FIG. 14 is a drawing exemplifying the heating temperature characteristics of the embodiment shown in FIG. 13.

FIG. 15 is a sectional view showing the major part of the heat treatment equipment of still further another embodiment of the present invention.

### BEST MODE FOR CARRYING OUT THE INVENTION

Hereinafter, an explanation will be made for one example of the heat treatment equipment of the present invention by referring to the drawings.

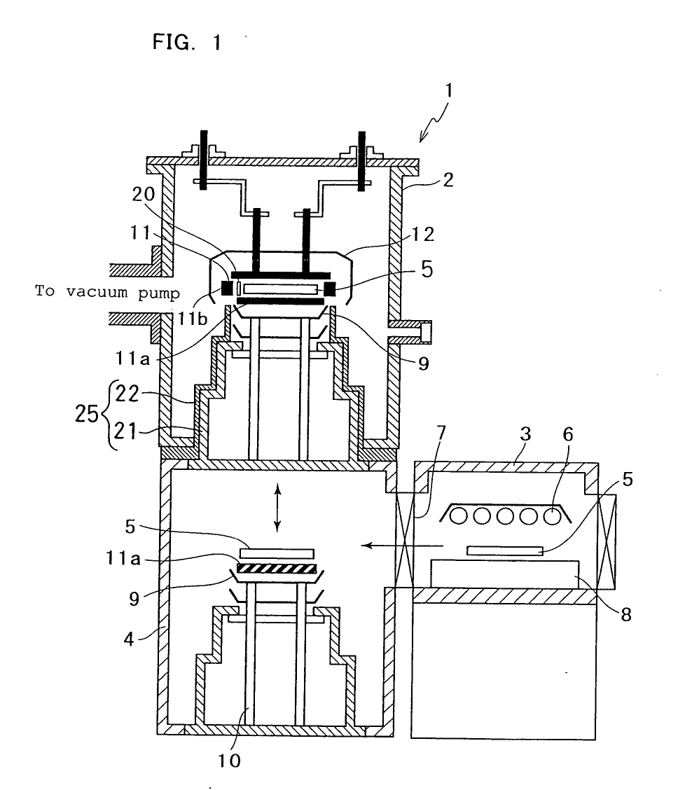

FIG. 1 is a schematic sectional view showing one example of the heat treatment equipment of the present invention. In FIG. 1, heat treatment equipment 1 is constituted with a heat chamber 2, a preheating chamber 3 and an anterior chamber 4 leading from the preheating chamber 3 to the heat chamber 2, and a substance to be treated 5 is transported sequentially from the preheating chamber 3 to the anterior chamber 4 and then to the heat chamber 2 to result in formation of single crystal sic.

As shown in FIG. 1, in the heat treatment equipment 1, the heat chamber 2, the preheating chamber 3 and the anterior chamber 4 are communicatively connected, thus making it possible to control each chamber under a prescribed pressure. Provision of a gate valve 7 and others for each chamber also makes it possible to attain a pressure control at each chamber. It is, therefore, possible to transport a substance to be treated 5 by a transportation means (not illustrated) in a furnace under a prescribed pressure even at the time of transportation of the substance to be treated 5 without exposure to open air, thereby preventing inclusion of impurities and others.

The preheating chamber 3 is provided with a heating means 6 such as a lamp (halogen lamp, etc.) or a rod heater and able to heat a substance rapidly at temperatures from 800° C. to 1000° C. as a heating furnace. A preferable heating means includes a lamp-type heating means such as a halogen lamp. The gate valve 7 is provided on a part at which the preheating chamber 3 is connected with the anterior chamber 4 so as to easily control the pressure of the preheating chamber 3 and the anterior chamber 4.

The substance to be treated 5 is transported in a state of being placed on a table 8 in the preheating chamber 3, heated in advance to a temperature exceeding 800° C. in a vacuum at a prescribed pressure of approximately 10⁻² Pa or lower and preferably at a pressure of approximately 10⁻⁵ Pa or lower, and then transported and placed on an elevating susceptor 9 provided in the anterior chamber 4, immediately after pressure is adjusted between the preheating chamber 3 and the anterior chamber 4.

The substance to be treated 5 which has been transported to the anterior chamber 4 is further transported from the anterior chamber 4 to the heat chamber 2 by an elevating transportation means 10 (partially illustrated). In this instance, the heat chamber 2 is kept by a vacuum pump (not illustrated) in a vacuum at a prescribed pressure of approximately 10⁻¹ Pa or lower, preferably at approximately 10⁻² Pa or lower, more preferably at approximately 10⁻⁵ Pa or lower, or after arrival at a vacuum at a prescribed pressure of approximately 10⁻² Pa or lower, preferably at approximately 10⁻⁵ Pa or lower, some inert gas is introduced to provide a rarefied gas atmosphere at approximately 10⁻¹ Pa or lower, preferably at approximately 10⁻² Pa or lower, the heat chamber is kept by the heater 11 in a range from approximately 800° C. to 2600° C., preferably from approximately 1200° C. to 2300° C.

The substance to be treated 5 is transported from the anterior chamber 4 to the heat chamber 2, with the heat chamber 2 kept in a state as explained above, by which the substance to be treated 5 can be heated rapidly to the prescribed temperature in a range from approximately 800° C. to 2600° C., preferably from approximately 1200° C. to 2300° C.

A reflecting mirror 12 is disposed around the heater 11 in the heat chamber 2 so that heat of the heater 11 can be reflected to concentrate on the substance to be treated 5 located inside the heater 11.

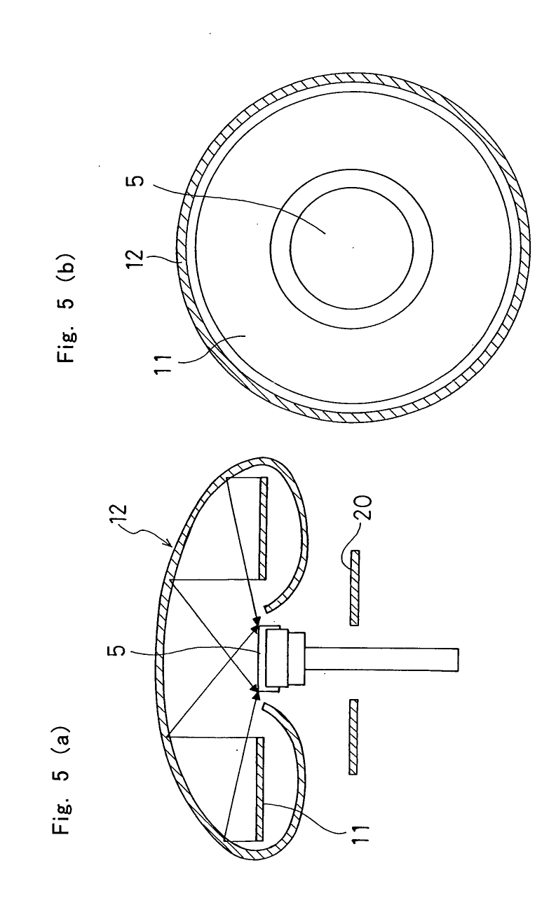

The reflecting mirror 12 may be available in an enclosure shape as shown in FIG. 1 or, for example, in a dome-shaped reflecting mirror 12 as shown in FIG. 5 (a) and FIG. 5 (b). The dome-shaped reflecting mirror 12 makes it possible to use a flat-type heating element for a heater 11 and concentrate the heat from the heater 11 effectively on the substance to be treated 5 even when the flat-type heater 11 is used.

A fitting part 25 of the transportation means 10 with the heat chamber 2 is constituted with a convex stepped part 21 provided on the transportation means 10 and a concave stepped part 22 formed on the heat chamber 2. The heat chamber 2 is then kept hermetically sealed by seal members such as an O ring (not illustrated) provided on each step of the stepped part 21 of the transportation means 10.

A contaminant removing mechanism 20 for removing contaminants leaking from the substance to be treated 5 so as not to contact with the heater 11 is provided inside the heater 11 in the heat chamber 2, thereby making it possible to prevent deterioration of the heater 11 after reaction with the contaminants. The contaminants include, for example, Si vapor produced during heat treatment of single crystal SiC by a liquid phase epitaxial method.

As explained above, since the contaminant removing mechanism is provided inside the heat chamber for removing contaminants such as silicon vapor leaking from a closed container, it is possible to prevent deterioration of heating means such as a heater provided inside the heat chamber by contaminants such as silicon vapor. In this instance, a vacuum pump and other general discharge means may be used as the contaminant removing mechanism.

There are no particular restrictions on the contaminant removing mechanism 20, as long as it is for removing contaminants leaking from the substance to be treated 5.

The heater 11 is a metal resistance heater made of graphite or tantalum, etc., and constituted with a base heater 11a disposed on the susceptor 9 and an upper heater 11b in which the side and the upper part are formed integrally into a tubular shape. The heater 11 is disposed so as to enclose a substance to be treated 5, thereby making it possible to give a uniform heating to the substance 5.

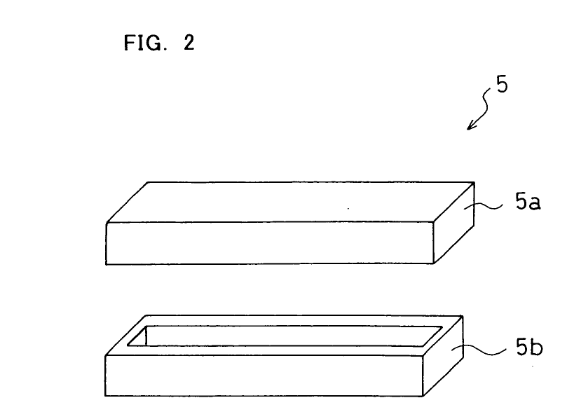

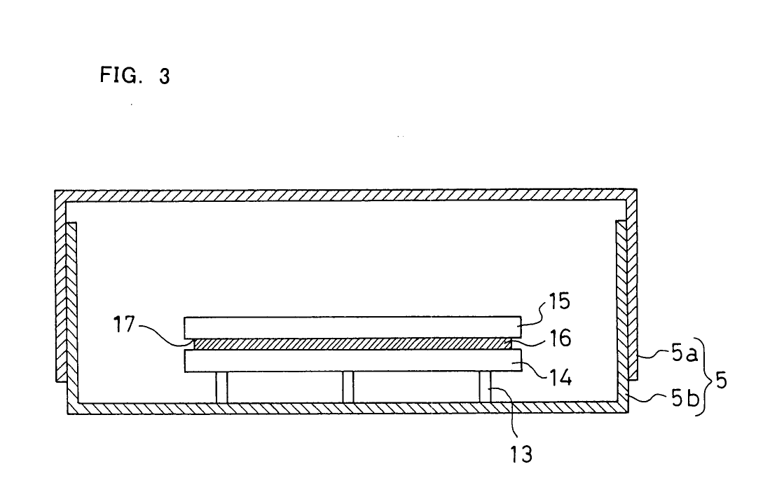

Further, the heat chamber 2 is not restricted to being heated only by the resistance heater described in the present embodiment but may be heated, for example, by a high-frequency induction heater.

Where a substance to be treated 5, for example, single crystal SiC, is subjected to heat treatment by a liquid phase epitaxial method, it is preferable that a closed container 5 constituted with an upper container cup wall 5a and a lower container cup wall 5b is used as shown in FIG. 2. The monocrystal SiC substrate 16 and the polycrystal SiC substrate are laminated and accommodated inside the closed container 5, as explained later, to perform heat treatment (see FIG. 3).

As shown in FIG. 2, the closed container 5 is constituted with the upper container cup wall 5a and the lower container cup wall 5b, each of which is made of either tantalum or tantalum carbide.

Since the closed container is made of tantalum or tantalum carbide, it is possible to prevent conversion of the closed container to SiC and reduce the pressure inside the heat chamber to approximately 10⁻² Pa or lower without fail.

It is also preferable that a play of the fitting part between the upper container cup wall 5a with the lower container cup wall 5b during fitting is approximately 2 mm or smaller. This makes it possible to prevent inclusion of impurities into the closed container 5. Further, when the play is set to be approximately 2 mm or smaller, a partial pressure of Si inside the closed container 5 can be controlled so as not to be lower than 10 Pa. Therefore, a partial pressure of SiC and that of Si inside the closed container 5 can be elevated, contributing to preventing sublimation of the monocrystal SiC substrate 16, polycrystal SiC substrates 14 and 15 and the very thin metallic Si melt layer 17. Further, where the play of the fitting part between the upper container cup wall 5a and the lower container cup wall 5b during fitting is larger than approximately 2 mm, controlling a partial pressure of Si inside the closed container 5 to a prescribed pressure is difficult and impurities may also enter into the closed container 5 through the fitting part, which is not favorable. The closed container 5 may be available in a circular form, in addition to a rectangular form as shown in FIG. 2.

As explained above, the present invention is heat treatment equipment, wherein the closed container is constituted with an upper container cup wall and a lower container cup wall, and the pressure inside the closed container is controlled so as to be higher than that inside the heat chamber to such an extent that silicon vapor leaks out from the fitting part of the upper container cup wall with the lower container cup wall, thereby preventing inclusion of impurities into the closed container.

Such a structure of the closed container makes it possible to prevent inclusion of impurities into the closed container, by which the purity of background, approximately 5×10¹⁵/cm³ or lower, can be attained.

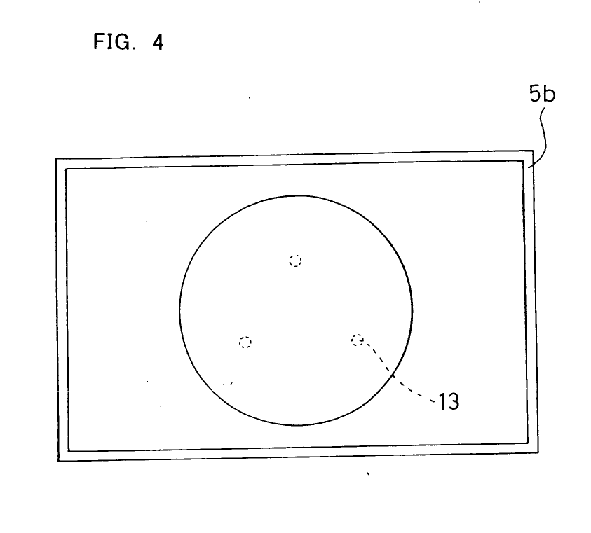

Further, as shown in FIG. 3 and FIG. 4, the lower container cup wall 5b is provided with three supports 13, which support a polycrystal SiC substrate 14 which will be used as a seed crystal to be explained later. The supports 13 may be available in a ring shape formed with SiC, etc., for example, not necessarily in a pin shape shown in the present embodiment.

FIG. 3 shows how a 6H-type monocrystal SiC substrate 16 which is placed inside the closed container 5 in a state that the upper container cup wall 5a is fitted with the lower container cup wall 5b and subsequently used as a seed crystal, a polycrystal SiC substrate 15 for holding the monocrystal SiC substrate 16 and a very thin metallic Si melt layer 17 formed between them are disposed. The very thin metallic Si melt layer 17 is formed during heat treatment, and a Si source of the very thin metallic Si melt layer 17 is available from a layer formed so as to give the thickness of approximately 10 μm to 50 μm on the surface of the monocrystal SiC substrate 16 which is used as a seed crystal by subjecting metal Si to CVD and others or Si powder placed thereon, the method of which shall not be restricted in particular.

As shown in FIG. 3, the monocrystal SiC substrate 16, polycrystal SiC substrates 14 and 15 and the very thin metallic Si melt layer 17 are placed on the supports 13 provided on the lower container cup wall 5b constituting the closed container 5, and housed inside the closed container 5. In this instance, the monocrystal SiC substrate 16 is cut into a desired size (between 10×10 mm and 20×20 mm) from wafer of the single crystal 6H—SiC produced by a sublimation method. Further, the polycrystal SiC substrates 14 and 15 are cut into a desired size from SiC, used as dummy wafer in Si semiconductor production processes, produced by a CVD method and used accordingly. These substrates 16, 14 and 15 are individually subjected to mirror-surface treatment to remove oils, oxide layers, metals and others on the surface by washing and others. In this instance, the polycrystal SiC substrate 14 located on a lower side is to prevent corrosion of the monocrystal SiC substrate 16 from the closed container 5, contributing to improvement in quality of single crystal SiC which is liquid-phase-epitaxially grown on the monocrystal SiC substrate 16.

A Si piece may also be placed inside the closed container 5 for preventing sublimation of SiC or evaporation of Si during heat treatment. A concomitant setting of the Si piece makes it possible to elevate a partial pressure of SiC and that of Si inside the closed container 5 by sublimation during heat treatment, contributing to preventing sublimation of the monocrystal SiC substrate 16, the polycrystal SiC substrates 14 and 15 and the very thin metallic Si melt layer 17. It is also possible to gain such a control that the pressure inside the closed container 5 is higher than that inside the heat chamber 2, thereby making it possible to constantly release Si vapor from the fitting part of the upper container cup wall 5a with the lower container cup wall 5b and prevent inclusion of impurities into the closed container 5.

The thus structured closed container 5 is placed inside the preheating chamber 3, set to be approximately 10⁻² Pa or lower, preferably approximately 10⁻⁵ Pa or lower, and then heated to a temperature exceeding approximately 800° C., preferably exceeding approximately 1000° C. by heating means 6 such as a lamp or a rod heater provided in the preheating chamber 3. It is preferable that the heat chamber 2 is also heated to a prescribed temperature in a range from approximately 800° C. to 2600° C., preferably from approximately 1200° C. to 2300° C. after the pressure is set to approximately 10⁻² Pa or lower, preferably to approximately 10⁻⁵ Pa or lower.

The closed container 5 preheated inside the preheating chamber 3 is transported to the susceptor 9 of the anterior chamber 4 by opening the gate valve 7 and then transported by the elevating means 10 into the heat chamber 2 which has been heated to a prescribed temperature in a range from approximately 800° C. to 2600° C., preferably from approximately 1200° C. to 2300° C.

Therefore, the closed container 5 is rapidly heated in a short time within approximately 30 minutes to a prescribed temperature in a range from approximately 800° C. to 2600° C., preferably from approximately 1200° C. to 2300° C. Heat treatment in the heat chamber 2 may be performed at temperatures which can melt a metal Si piece placed together inside the closed container 5. In the present embodiment, heat treatment shall be performed at a prescribed temperature ranging from approximately 1200° C. to 2300° C. Wettability with melted Si and SiC are increased accordingly at higher treatment temperatures, and melted Si is more easily permeated between the monocrystal SiC substrate 16 and the polycrystal SiC substrates 14 and 15 due to capillarity, thereby making it possible to interpose a very thin metallic Si melt layer 17 with a thickness of approximately 50 μm or less between the monocrystal SiC substrate 16 and the polycrystal SiC substrates 14 and 15.

Since the heat treatment equipment of the present embodiment is able to provide heating in a short time to a prescribed temperature in a range from approximately 800° C. to 2600° C., preferably from approximately 1200° C. to 2300° C., crystal growth can be completed in a shorter time to attain an effective crystal growth.

Further, heat treatment may be performed for an appropriately selected time so as to form single crystal SiC in a desired thickness. Metal Si which is used as an Si source will melt in a greater quantity during heat treatment when used in a greater quantity. Further, when very thin metallic Si melt layer is formed in a thickness of approximately 50 μm or more, a metal Si melt becomes unstable to prevent transportation of C, which is not suitable for growing single crystal SiC. Further, Si unnecessary for forming single crystal SiC is melted and deposited at the bottom of the closed container 5, which necessitates removal of metal Si solidified again after formation of single crystal SiC. Therefore, size and thickness of the metal Si are appropriately selected according to the size of single crystal SiC to be formed.

A brief explanation will be made for the growth mechanism of single crystal SiC. In association with heat treatment, melted Si enters into a space between the monocrystal SiC substrate 16 and the upper polycrystal SiC substrate 15, forming the metal Si melt layer 17 into a thickness of approximately 30 μm to 50 μm on the interface between these substrates 16 and 15. The metal Si melt layer 17 is thinner in thickness or approximately 30 μm accordingly as heat treatment is performed at higher temperatures. Then, C atoms flowing from the polycrystal SiC substrate 2 are supplied through the Si melt layer to the monocrystal SiC substrate 16, and liquid-phase epitaxially grown (hereinafter referred to as LPE) as 6H—SiC single crystal on the monocrystal SiC substrate 1. As explained above, no thermal convection takes place during heat treatment due to a small space between the monocrystal SiC substrate 16, which is subsequently used as a seed crystal, and the polycrystal SiC substrate 14. Therefore, an interface between the single crystal SiC to be formed and the monocrystal SiC substrate 16 to be used as a seed crystal is made very smooth and free of any distortion and others. Therefore, very smooth single crystal SiC can be formed.

Further, nucleation of SiC is prevented during heat treatment, and therefore formation of fine grain boundaries of single crystal SiC to be formed can be prevented. Since melted Si enters only into a space between the monocrystal SiC substrate 16 and the polycrystal SiC substrate 15 in the method for growing single crystal SiC of the present embodiment, no impurities enter into growing single crystal SiC, thereby making it possible to form single crystal SiC having a high purity of background, approximately 5×10¹⁵/cm³ or lower.

The heat treatment equipment of the present embodiment so far explained comprises a heat chamber wherein a substance to be treated is heated in a short time in a range from approximately 800° C. to 2600° C., preferably from approximately 1200° C. to 2300° C. in a vacuum at a pressure of approximately 10⁻² Pa or lower, preferably at approximately 10⁻⁵ Pa or lower or in a rarefied gas atmosphere to which inert gas is introduced after a prior arrival at a vacuum at a pressure of approximately 10⁻² Pa or lower, preferably at a pressure of approximately 10⁻⁵ Pa or lower, an anterior chamber connected to the heat chamber and equipped with a transportation means for transporting the substance to be treated to the heat chamber, and a preheating chamber connected to the anterior chamber and heating in advance the substance to be treated to a temperature exceeding approximately 800° C. in a vacuum at a pressure of approximately 10⁻² Pa or lower, or preferably approximately 10⁻⁵ Pa or lower.

Then, according to the heat treatment equipment of the present embodiment, in a vacuum at a pressure of approximately 10⁻² Pa or lower, preferably at a pressure of approximately 10⁻⁵ Pa or lower or in a rarefied gas atmosphere, to which some inert gas is introduced, at approximately 10⁻¹ Pa or lower, preferably at approximately 10⁻² Pa or lower, after a prior arrival at a higher vacuum at a pressure of approximately 10⁻² Pa or lower, preferably at a pressure of approximately 10⁻⁵ Pa or lower, a substance to be treated can be heated in a short time to a prescribed temperature in a range from approximately 800° C. to 2600° C., preferably from approximately 1200° C. to 2300° C. Therefore, where single crystal SiC is formed as a substance to be treated, it is possible to form single crystal SiC having a broad terrace of approximately 10 μm or more on the surface, which could not be attainable by a conventional liquid phase epitaxial method (LPE method) for growing single crystal SiC.

Further, the heat treatment method according to the embodiment of the present invention is a heat treatment method, wherein after the substance to be treated is heated in advance to a temperature exceeding approximately 800° C. in the preheating chamber kept in a vacuum at a pressure of approximately 10⁻² Pa or lower, preferably approximately 10⁻⁵ Pa or lower, the substance is transported to the heat chamber, which is heated in advance to a prescribed temperature in a range from approximately 800° C. to 2600° C. or preferably from approximately 1200° C. to 2300° C., in a vacuum at a pressure of approximately 10⁻² Pa or lower, preferably approximately 10⁻⁵ Pa or lower or in a rarefied gas atmosphere to which inert gas is introduced after a prior arrival at a vacuum at a pressure of approximately 10⁻² Pa or lower, preferably at a pressure of approximately 10⁻⁵ Pa or lower, thereby heating the substance to be treated in a short time to a prescribed temperature in a range from approximately 800° C. to 2600° C., preferably in a range from approximately 1200° C. to 2300° C.

Further, the heat treatment method used in the liquid phase epitaxial method for growing single crystal silicon carbide according to the embodiment of the present invention is a heat treatment method, wherein a monocrystal silicon carbide substrate as a seed crystal and a polycrystal silicon carbide substrate are piled up and placed inside a closed container to perform high-temperature heat treatment, by which very thin metallic silicon melt layer is interposed between the monocrystal silicon carbide substrate and the polycrystal silicon carbide substrate during heat treatment and single crystal silicon carbide is liquid-phase-epitaxially grown on the monocrystal silicon carbide substrate.

Then, the closed container is heated in advance to a temperature exceeding approximately 800° C. in a preheating chamber at a pressure of approximately 10⁻² Pa or lower, the closed container is reduced in pressure to approximately 10⁻⁵ Pa or lower, the container is transported and placed in the heat chamber, which is in advance heated to a prescribed temperature in a range from approximately 1400° C. to 2300° C., in a vacuum at a pressure of approximately 10⁻² Pa or lower, preferably at a pressure of 10⁻⁵ Pa or lower or in a rarefied gas atmosphere to which inert gas is introduced after a prior arrival at a high vacuum at a pressure of 10⁻⁵ Pa or lower, by which the monocrystal silicon carbide substrate and the polycrystal silicon carbide substrate are heated in a short time to a prescribed temperature in a range from approximately 1400° C. to 2300° C. to produce single crystal silicon carbide which is free of fine grain boundaries and approximately 1/cm² or lower in density of micropipe defects on the surface.

In addition, when the closed container is transported to the heat chamber, no temperature difference is provided in an axial direction of the closed container, but temperature gradient is provided in a plane direction of the closed container, and the temperature gradient is arbitrarily controlled to prevent formation of fine grain boundaries. The axial direction of the closed container refers to a direction at which the monocrystal silicon carbide substrate and polycrystal silicon carbide substrate are laminated inside the closed container, and the plane direction of the closed container refers to a direction vertical to the direction of lamination, namely, a plane direction of crystal surface.

Heat treatment can be performed in a state of heat balance, because no temperature difference is made in an axial direction of the closed container or no temperature difference is made between the monocrystal SiC substrate and the polycrystal SiC substrate. Further, low concentrations of metal Si melt will result in prevention of thermal convection and therefore result in preventing the occurrence of defects at an initial stage of crystal growth to the completion stage. Further, since nucleation is prevented during heat treatment, fine grain boundaries of single crystal SiC to be formed can be prevented from being formed. Production costs can be greatly reduced because simple heat treatment equipment is used and no strict temperature control is required during heating. In addition, a temperature gradient is provided in a plane direction of the closed container to arbitrarily control the temperature gradient, by which single crystal SiC can be grown so as to move fine grain boundaries from a high temperature side of the temperature gradient to a low temperature side at the time of growing single crystal SiC and single crystal SiC can consequently be formed to be approximately 1/cm² or lower in density of micropipe defects.

The very thin metallic Si melt layer is approximately 50 μm or lower in thickness.

Since a very thin metallic Si melt layer which is interposed between the monocrystal SiC substrate and the polycrystal SiC substrate during heat treatment is approximately 50 μm or lower, preferably approximately 30 μm or lower, C dissolved from polycrystal SiC substrate is transported by diffusion to the surface of monocrystal SiC substrate, thereby promoting the growth of single crystal SiC. Where the very thin metallic silicon melt layer is approximately 50 μm or greater in thickness, metallic silicon melt becomes unstable to prevent transportation of C, which is not suitable for growing single crystal SiC.

Since the present invention is able to perform a local liquid phase epitaxial growth at high temperatures in the same environment as that of high-temperature heat treatment by a conventional sublimation method and others, it is free of micropipe defects resulting from a seed crystal and able to block such micropipe defects. The growth surface is constantly in contact with Si melt and Si is formed in an excessive state, thereby preventing occurrence of defects resulting from a shortage of Si. Further, since an area of the used Si melt in contact with the outside is very small, impurities can be prevented from entering into the growth surface, and high-quality high-performance single crystal SiC can be grown which is high in purity and excellent in crystallinity. The present growth method is able to attain crystallization at much higher temperatures in a shorter time than a conventional LPE method, thereby making it possible to greatly increase the growth speed and provide high-quality single crystal SiC very effectively, as compared with a conventional LPE method. In addition, the present method does not require a strict control of temperature gradient at the time of growing single crystal and therefore can be carried out by simple equipment. Single crystal SiC is better in the ability to realize high-temperature, high-frequency, voltage resistance and environment resistance than conventional semiconductor materials such as Si and GaAs and expected as semiconductor materials for power devices and high frequency devices. In view of these facts, commercialization can be promoted.

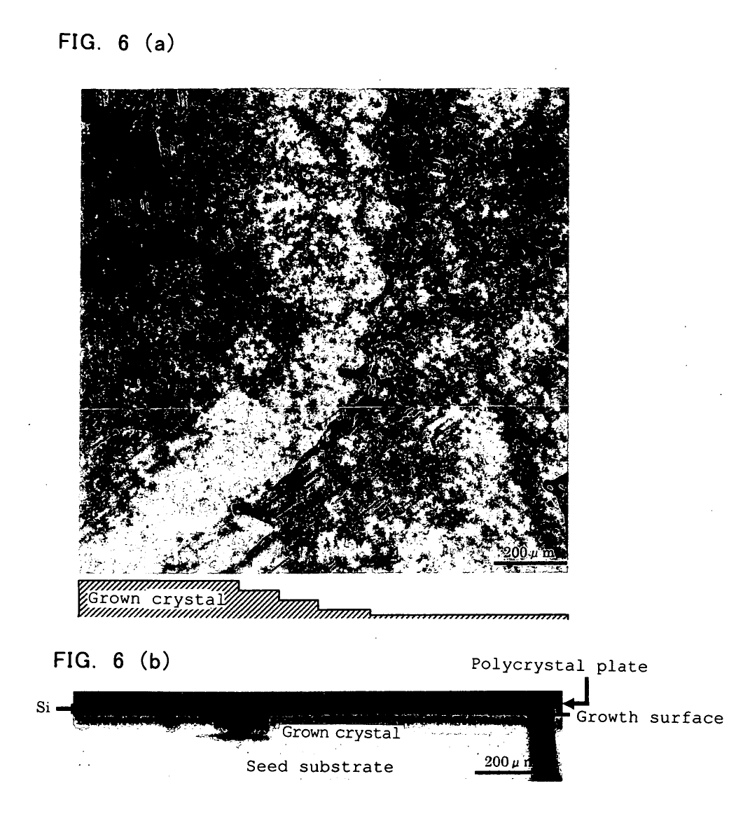

FIG. 6 (a) and FIG. 6 (b) are micrographs showing the surface state of single crystal SiC grown by the previously-explained method. FIG. 6 (a) is a micrograph showing the surface morphology and FIG. 6 (b) is a micrograph showing its cross section. As shown in FIG. 6 (a) and FIG. 6 (b), the surface of crystal growth by the LPE method is observed as a very flat terrace and step structure.

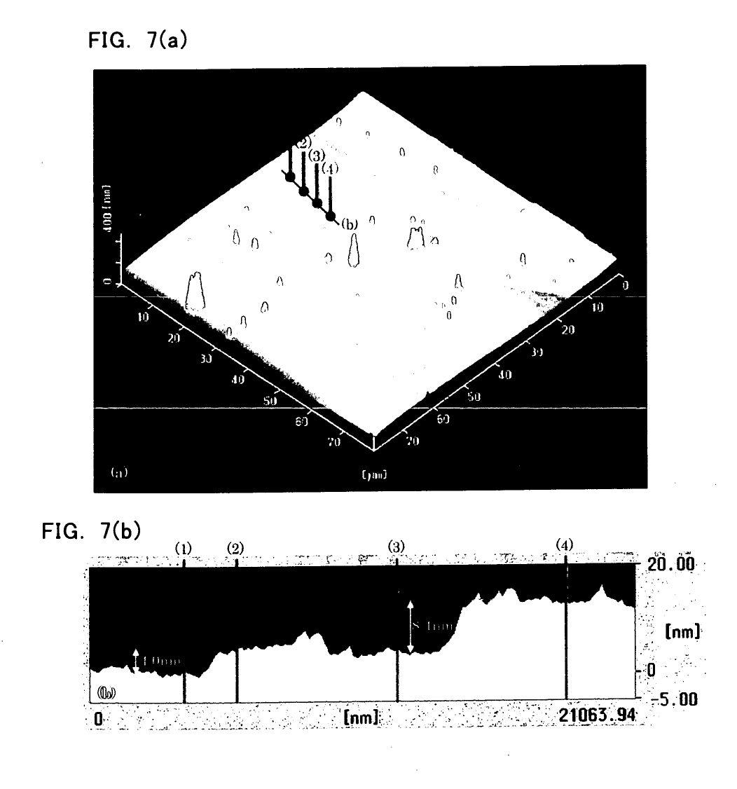

FIG. 7 (a) and FIG. 7 (b) are drawings showing the result obtained by observing the surface by atomic force microscope (hereinafter referred to as AFM). As observed in FIG. 7 (a) and FIG. 7 (b), the respective step heights are found to be approximately 4.0 nm and 8.4 nm, which are the height equivalent to integral multiple on the basis of a three-molecular layer of SiC molecule (height of one SiC molecular layer is 0.25 nm). As explained above, the surface is found to be very flat.

The surface of the single crystal SiC has an atomic order step as a minimum unit of a three-molecular layer and a broad terrace, and the terrace is approximately 10 μm or more in width.

Since a width of the terrace is approximately 10 μm or more, the growth surface does not need surface treatment by machining or others after formation of single crystal SiC, thus making it possible to give a final product without a machining process.

As apparent from the micrographs of the surface morphology shown in FIG. 6 (a) and FIG. 6 (b), no micropipe defects are found on the surface. Thus, single crystal SiC obtained by the heat treatment equipment of the present invention is quite small in density of the micropipe defects formed on the surface or approximately 1/cm² or less, broad in width of the terrace or approximately 10 μm or more, and found to be flat and small in defects.

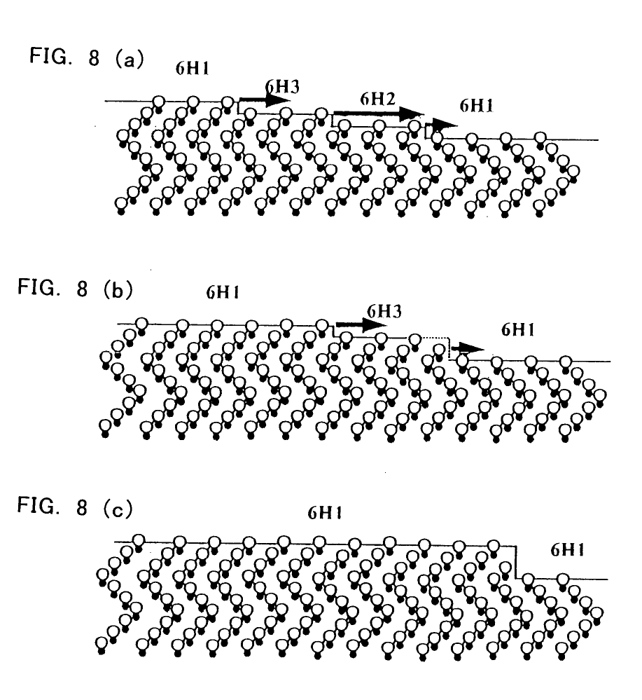

In general, crystal epitaxial growth is performed for each molecular layer. However, single crystal SiC according to the present embodiment is constituted with broad terraces of approximately 10 μm or more and steps of height as a minimum unit of a three-molecular layer on the surface. This fact is suggestive of step bunching occurring in the course of crystal growth. This step bunching mechanism may be explained by the effect of surface free energy during crystal growth. Single crystal 6H—SiC according to the present embodiment has two types of directional lamination cycle, namely, ABC and ACB, as unit of lamination cycle. In this instance, as shown in FIG. 8 (a), FIG. 8 (b) and FIG. 8 (c), three types of the surface can be specified by assigning a number from a layer bending in lamination direction as 1, 2 and 3. Then, energy on each plane can be determined as follows (T. Kimoto, et al., J. Appl. Phys. 81 (1997) 3494-3500).

6H1=1.33 meV

6H2=6.56 meV

6H3=2.34 meV

A terrace spreads at a different speed because energy is different depending on a plane. More particularly, the terrace grows more rapidly as surface free energy of each plane is greater. As shown in FIG. 8 (a), FIG. 8 (b) and FIG. 8 (c), step bunching takes place for every three cycles. The present embodiment is different in the number of dangling bonds coming from the step surface for every one step due to a difference in lamination cycle (ABC or ACB), and additional step bunching may take place as a unit of three molecules due to a difference in the number of dangling bonds coming from an edge of the step. An advanced speed of one step is considered to be slow at a place of one dangling bond coming from a step and fast at a place of two dangling bonds. Therefore, the step bunching proceeds by the unit height of half-integral multiple of the lattice constant in 6H—SiC, and the surface of single crystal SiC is considered to be covered with steps of the height as a minimum unit of a three-molecular layer and flat terraces after growth.

As explained so far, in single crystal SiC according to the present invention, terraces are formed by step bunching and steps are therefore formed in a concentrated way around the edge of the single crystal SiC. FIG. 6 (a), FIG. 6 (b), FIG. 7 (a) and FIG. 7 (b) described previously are observations of an edge of single crystal SiC for observing the step part.

Further, single crystal SiC obtained by the heat treatment equipment according to the present embodiment is quite high in growth temperature as compared with liquid phase growth temperatures in conventional single crystal SiC or in a range from approximately 1400° C. to 2300° C., and can be heated in a short time to temperatures in a range from approximately 1400° C. to 2300° C. Concentrations of C dissolved in Si melt formed between monocrystal SiC to be used as a seed crystal and polycrystal SiC will increase with an increase in growth temperatures. Further, in association with an increase in temperature, it is considered that C may diffuse greatly in the Si melt. Therefore, since a source of C is in close proximity to the seed crystal, a high growth speed, for example, approximately 500 μm/hr, may be attained depending on the conditions.

As explained so far, single crystal SiC according to the present embodiment is 1/cm² or less in density of micropipe defects on the surface, and a broad terrace which is approximately 10 μm or more is formed, thereby eliminating the need for performing surface treatment such as machining after formation of single crystal SiC. Further, it is small in the number of crystal defects, etc., and can be used as light emitting diodes and various types of semiconductor diodes. In addition, the crystal grows not depending on temperature but on surface energy of a seed crystal and crystal of C sources, thereby eliminating the need for conducting a strict temperature control for the treatment furnace and realizing a great reduction in production costs. Further, since monocrystal SiC as a seed crystal is in close proximity to polycrystal SiC as a C source, it is possible to prevent thermal convection during heat treatment. Also, there is hardly any difference in temperature between the monocrystal SiC as a seed crystal and the polycrystal SiC as a C source, and heat treatment may be performed in a state of heat balance.

As so far explained, crystal growth of single crystal SiC takes place along a plane direction of the crystal surface, and providing temperature gradient in a plane direction of the closed container makes it possible to give orientation to the growth direction of crystals from a high temperature side to a low temperature side. Temperature gradient can be given by a method in which temperature is made different between side heaters 11b located on the wall sides of the closed container 5 of the heater 11 disposed on the heat chamber 2. In this instance, growth speed of crystals can be controlled by controlling an angle of temperature gradient, thereby preventing formation of fine grain boundaries on the crystal surface.

Further, in the present embodiment, 6H—SiC was used as a seed crystal, but 4H—SiC may also be used.

In the present embodiment, (0001) Si was used as a seed crystal, but a substance with another plane orientation, for example, (11-20), may also be used.

Where the surface plane orientation is (0001) Si plane, the plane is lower in surface energy than other crystal planes, therefore higher in nucleation energy during growth, and difficult in nucleation. For the above reasons, single crystal SiC with a broad width of terrace is provided after liquid phase growth. Further, surface plane orientation shall not be restricted to (0001) Si plane but any crystal plane of 4H—SiC and 6H—SiC may be used.

The present invention is able to control a size of single crystal SiC formed by appropriately selecting a size of the monocrystal SiC as a seed crystal and that of the polycrystal SiC substrate as a C source. Also, there is also hardly any chance of a distortion occurring between the single crystal SiC to be formed and the seed crystal, thereby providing single crystal SiC, the surface of which is extremely smooth. The single crystal Sic may also be used as a surface modifying film.

Further, the monocrystal SiC as a seed crystal and the polycrystal SiC as a C source are alternately laminated or disposed from side to side to perform heat treatment according to the above-described method, by which single crystal SiC can be produced simultaneously in a great quantity.

Further, in the method for producing single crystal SiC according to the present invention, impurities of group III metals such as Al and B are in advance added to the polycrystal SiC substrate and metal Si or a gas containing elements such as nitrogen, Al, and B for controlling conductivity of SiC is fed into the atmosphere during growth, by which conductivity of p-type or n-type of grown crystal can be controlled arbitrarily.

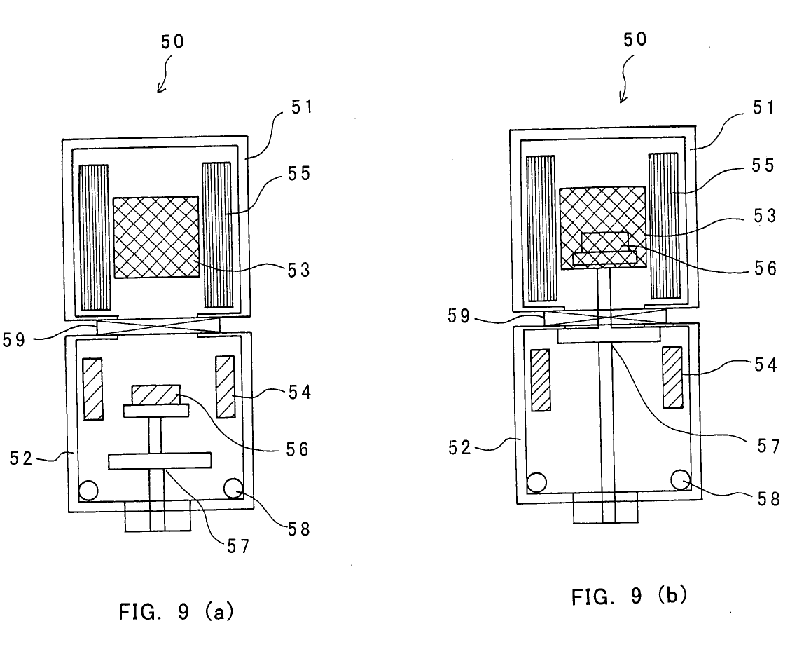

Then, an explanation will be made for preferred embodiments of the heat treatment equipment for carrying out the heat treatment method of the present invention by referring to FIG. 9 (a), and FIG. 9 (b) through FIG. 15.

FIG. 9 (a) and FIG. 9 (b) are sectional views showing major parts of other preferred embodiments of the heat treatment equipment for carrying out by the heat treatment method of the present invention.

As shown in FIG. 9 (a) and FIG. 9 (b), the heat treatment equipment of the present embodiment is provided with a high-temperature heating furnace 50.

The high-temperature heating furnace 50 is mainly constituted with a main heating tank 51, a preheating tank 52, a vacuum valve 59 enables the main heating tank 51 and the preheating tank 52 communicatively connected with and detached from each other, and a jig and an elevating table 57 for allowing a sample 56 (substance to be treated) to move between the main heating tank 51 and the preheating tank 52. The main heating tank 51 and the preheating tank 52 are provided respectively with a refractory metal main heater 53 and a refractory metal preheating heater 54.

A refractory metal reflector 55 is also provided inside the main heating tank 51 to provide an effective heating by the refractory metal main heater 53. Further, an adsorption trap 58 is provided inside the preheating tank 52 to maintain the pressure inside the preheating tank 52 at a prescribed level.

Further, a heating part of the main heating tank, namely, the heater 53, is constituted with a tubular main heater made of a refractory metal (not illustrated) and a flat auxiliary heater. Controlled heating of these two heaters and change in location of the sample make it possible to improve the soaking property of temperature inside a disk-shaped soaking region and provide temperature gradient in a plane direction inside the disk-shaped heating region.

Graphite responsible for gas generation is not used as a heat source or a heater inside the main heating tank 51 and the preheating tank 52 or an insulating material enclosing the heat source, but tungsten (W), a refractory metal, smaller in gas adsorption is used mainly as a heating element and a reflector for heat insulation.

In the heat treatment equipment of the present embodiment, when the sample 56 is at first placed in a preheating tank 52, the preheating tank 52 is discharged in vacuum from an ambient pressure by a vacuum pump (not illustrated) and heated from room temperature to approximately 800° C. by the preheating heater 54 to remove adsorbed gas and contained gas out of the tank by the vacuum pump for degassing gas adsorbed to the sample 56 and gas contained therein.

A heating source of the preheating tank includes a halogen lamp or an Xe lamp equipped with a reflecting mirror for concentrating near-infrared rays on a sample or an infrared heating lamp equipped with an infrared ray generating film on the outer surface of the lamp tare for attaining a rapid heating in a short time.

After completion of degassing the sample 56, the sample is transported within one minute to the main heating tank 51, which is in advance heated and discharged in a vacuum and kept clean at high temperatures (refer to FIG. 9 (b)). The vacuum valve 59 is opened and the elevating table 57 is elevated to conduct the transportation. The main heating tank 51 constantly kept at a prescribed high temperature or at a temperature exceeding approximately 800° C., preferably in a range from approximately 1800° C. to 2600° C. in a high vacuum constantly at a pressure of approximately 10⁻³ Pa or lower or in a rarefied gas atmosphere kept at approximately 10⁻² Pa by introduction of some inert gas after a prior arrival at a high vacuum.

For example, where single crystal silicon carbide is subjected to heat treatment by the liquid phase epitaxial method, the main heating tank can be used preferably in a range from approximately 1200° C. to 2300° C. and more preferably from approximately 1400° C. to 2300° C.

Then, after completion of transportation of the sample 56 to the main heating tank 51, the sample 56 can be heated smoothly to a prescribed high temperature in a range from approximately 1200° C. to 2600° C., namely, an optimal treatment temperature of the sample 56. Since the main heating tank 51 has been heated in advance, the tank is able to keep uniform high temperatures for a time necessary for conducting the heat treatment. Provision of the refractory metal reflector 55 makes it possible to heat the sample 56 effectively due to heat radiation.

The heater or a heating part of the main heating tank 51 is constituted with a tubular main heater and a flat auxiliary heater, each of which is made of a refractory metal.

Further, wave energy generated from a W heater is expressed by the following formula.

Wave energy of W=spectral emissivity of W×wave energy of ideal black body.

Wave energy of the ideal black body can be easily determined by referring to Plank's law of radiation.

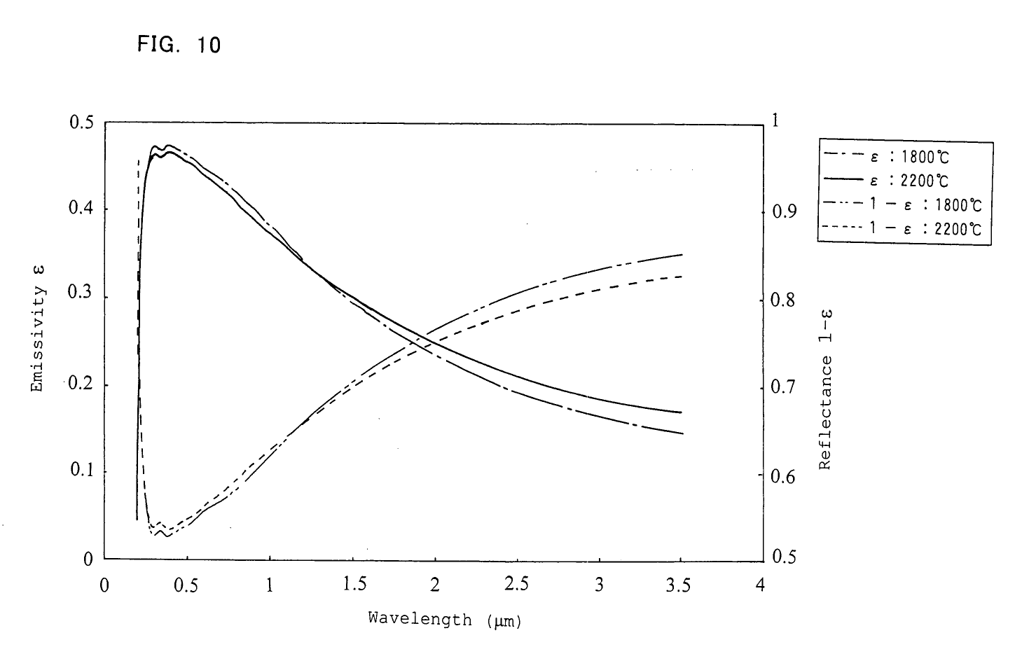

FIG. 10 is a drawing showing the spectral emissivity and reflectance of W. The spectral emissivity shown in the drawing is calculated from the formula shown below and described in the literature of “The Science Of Incandescence” authored by “Dr. Milan R. Vukcevich.”
ε[λ,T]=a[λ]−b[λ,T]{(T−1600)/1000}
wherein, ε is denoted as emissivity; λ, as wavelength ([μm]; and T, as temperature [K].

Further, the reflectance given in FIG. 10 was calculated from the following formula according to Kirchhoff's law.
R=1−ε
wherein R is denoted as reflectance and ε, emissivity.

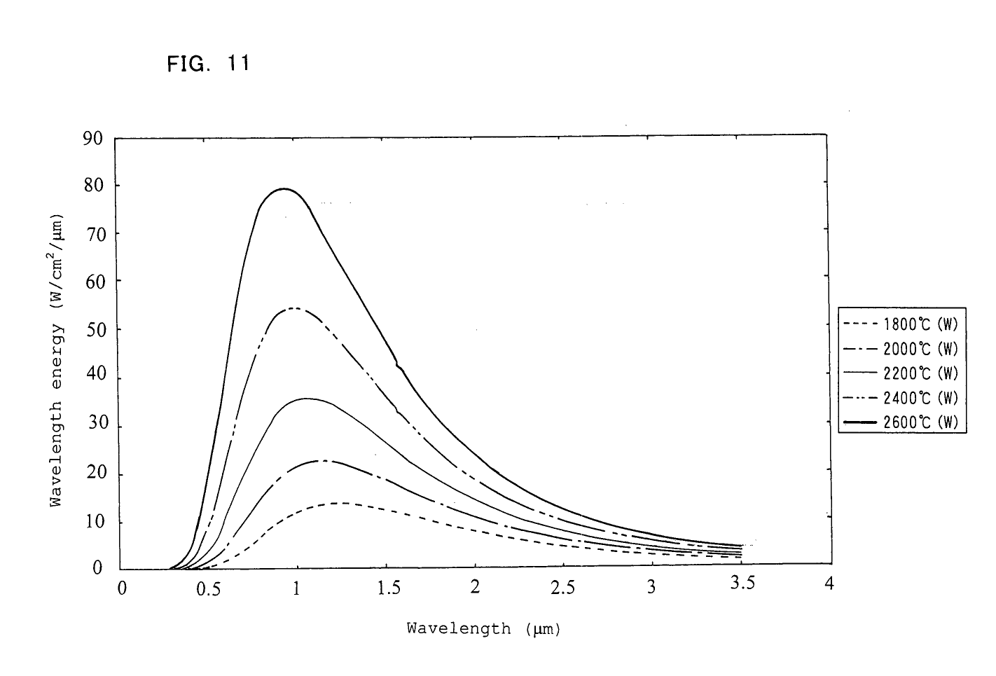

FIG. 11 shows wave energy characteristics at high temperature regions of W from 1800° C. to 2600° C. according to Plank's law of radiation.

The result of FIG. 11 has revealed that wave energy in the high temperature regions of W from 1800° C. to 2600° C. has a peak between 1.0 μm and 1.5 μm and mostly falls under the wavelength regions from 0.4 μm to 3.5 μm. In other words, a reflecting material which has a high reflection property in wavelength from approximately 0.4 μm to 3.5 μm is able to give an effective heating to materials inside a furnace.

Further, Table 1 shows some examples of metals and compounds usable in this temperature region.

TABLE 1

| | |
|---|---|
| Refractory metals | Nb, Mo, W, Ta |
| Highly heat-resistant | WC, ZrC, TaC, HfC, MoC, BN |
| materials | |

With reference to the above metals and materials, the present heat treating equipment comprises a high temperature heating furnace having a high purity atmosphere in which the main heating tank is set to conduct heat treatment at a prescribed temperature from approximately 1200° C. to 2600° C., wherein a heating part of the high temperature heating furnace is made of a refractory metal such as W or Ta, a component used at thermal reflectance and heat insulating regions enclosing high temperature regions is provided with a composite structure made of a refractory metal material selected from W, Ta or Mo, the component made of a refractory metal at the heat-blocking region is provided on the surface with an infrared-ray reflecting film having any given length region ranging from approximately 0.4 μm to 3.5 μm which reflects an emission wavelength region of the heating part.

To be more specific, a heater is made of W, and a reflector is made of W and Ta in which the wavelength mainly composed of infrared ray regions is from approximately 0.4 μm to 3.5 μm.

As apparent from FIG. 11, the wavelength energy derived from radiation of W at 2200° C. exhibits a peak at approximately 1.1 μm. In this instance, reflectance of W is approximately 0.65. Further, at a region from approximately 1.1 μm to 3.0 μm where wavelength energy is relatively high, reflectance increases with an increase in wavelength, reaching at 0.8 in wavelength of 3.0 μm. In other words, reflection properties of W are considered sufficient as a reflector for the W heater in a clean high-purity atmosphere.

Further, in terms of characteristics related to emissivity and reflectance of W at a high temperature given in FIG. 10, Table 2 shows an example of the design of the metal reflector 55 enclosing the W heater and samples. Individual reflectors 55 enclose the heater 53 and the sample 56 in a hermetic state and a distance between each reflector 55 is approximately 3 mm. Further, Table 3 shows an example of constituting highly heat-resistant metal oxides and infrared ray reflecting films formed on the refractory metal reflector 55.

TABLE 2

| | |
|---|---|
| 9-layer type | Ta/Ta/Ta/Ta/Mo/Mo/Mo/Mo/Mo |
| 11-layer type | W/W/W/W/W/Mo/Mo/Mo/Mo/Mo/MO |

TABLE 3

| | |
|---|---|
| High temperature region | W metal reflector + WC |
| Moderate temperature region | Mo metal reflector + Au |

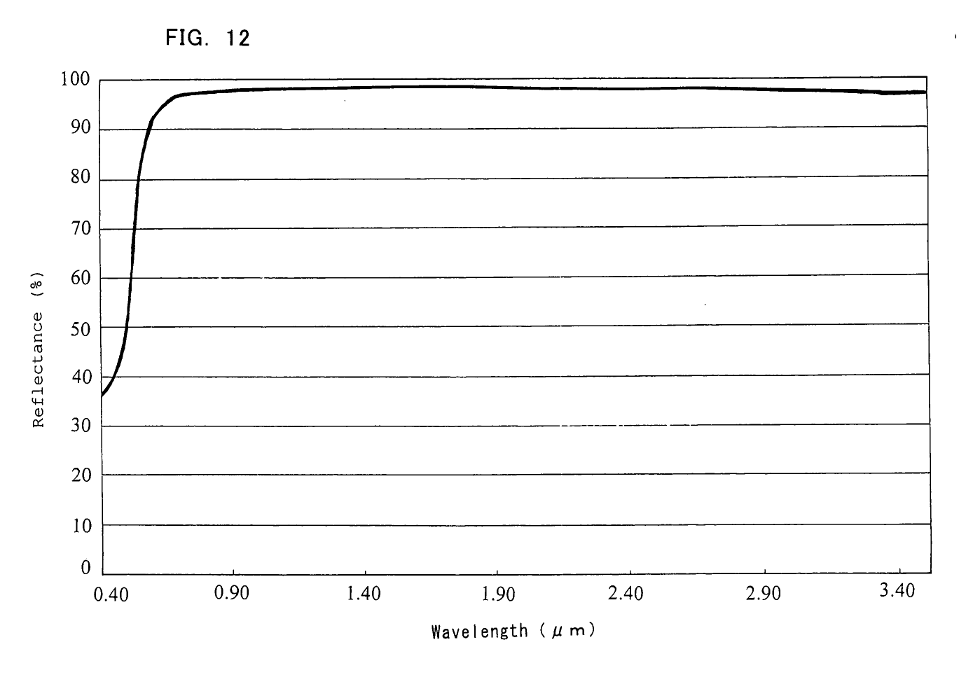

W which is a refractory metal is approximately 3400° C. in melting point, and Mo is approximately 2620° C. Further, WC given as an example in the present embodiment is approximately 2720° C. in melting point and Au is approximately 1060° C. Therefore, WC higher in melting point and well agreeable with a substrate is used on W, whereas Au relatively lower in melting point is used on Mo. The reflectance of WC at a near-infrared ray region is relatively high on a smooth flat surface, though depending on film-forming conditions. Since Au is a highly reflective material with the reflectance of approximately 95% or more in the region, Au film is formed on Mo which is in a moderate temperature region to a higher temperature region (outside) due to a lower melting point of Au. FIG. 12 shows spectral reflectance characteristics in the wavelength region of Au reflective layer from 0.4 μm to 3.5 μm.

In the present embodiment, as explained so far, the heat insulation region constituted with refractory metal plates enclosing the heater part of the main heating tank is provided with a composite structure composed of a heat insulation layer and a heat-ray reflective layer, each layer has functions of insulating heat and reflecting heat rays, the surface of the refractory metal plates constituting the heat insulation region is coated with highly heat-resistant metal carbides such as WC, TaC, MoC, ZrC, HfC and BN or with metal nitrides solely or in combination thereof, thereby providing functions of preventing deterioration or deformation of refractory metals, the surface of the refractory metal as a heat-ray reflective layer is coated with an infrared ray reflecting film made of Au or others, thereby providing functions of reflecting at a high efficiency the region of any given emission wavelength from approximately 0.4 to 3.5 μm.

The heat treatment equipment according to the present embodiment comprises a high-temperature heating furnace wherein the inside of a vacuum high-temperature furnace is composed of two or more divided tanks, the inside of each of these plurality of tanks is constituted with a main heating tank and a preheating tank, the preheating tank is heated from a room temperature to approximately 800° C. for degassing the gas mainly adsorbed to a sample and the gas contained inside the sample, after completion of the degassing, the sample is smoothly transported to the main heating tank which is in advance discharged of air by heating and vacuum treatment and kept clean and at high temperatures, the main heating tank is constantly heated to a prescribed high temperature in a range from approximately 800° C. to 2600° C. constantly at a pressure of approximately 10⁻³ Pa or lower or in a rarefied gas atmosphere at any given pressure from ambient pressure to approximately 10⁻³ Pa by introduction of some inert gas after a prior arrival at approximately 10⁻³ Pa or lower pressure, the preheating tank has the function of discharging air from ambient pressure for supplying and removing a sample to a pressure level which is the same as that attained by the main heating tank necessary for transporting the sample to or from the main heating tank, and after a preheating of the sample from room temperature to approximately 800° C., a quick transportation to the main heating tank enables to attain a high-temperature and high-purity atmosphere at a temperature exceeding approximately 800° C., preferably at a temperature exceeding 1200° C., more preferably at a temperature in a range from 1800° C. to 2600° C. which are optimal temperatures for treating the sample.

Further, the main heating tank is preferably in a range from approximately 1200° C. to 2300° C. and more preferably in a range from approximately 1400° C. to 2300° C. where, for example, single crystal silicon carbide is subjected to heat treatment according to the liquid phase epitaxial method.

Further, the heat treatment equipment according to the present embodiment is heat treatment equipment having a high-speed and high-temperature heating furnace, wherein a vacuum high-temperature furnace is divided into two tanks or a main heating tank and a preheating tank for rapid heating of a sample, and at the same time for keeping a high-purity atmosphere, the inside of each tank is provided with an individually independent vacuum discharge system or an individually independent gas introduction system and capable of keeping an ambient pressure atmosphere, and the main heating tank and the preheating tank are mutually kept integrated or divided by opening or closing a cut-off valve, the heat treatment equipment having a high temperature heating furnace, wherein the main heating tank is kept at a high temperature exceeding approximately 800° C., preferably at a temperature exceeding approximately 1200° C., more preferably in a range from 1800° C. to 2600° C. constantly at a pressure of approximately 10⁻³ Pa or lower during a regular use or in a rarefied gas atmosphere of any given pressure from ambient pressure to approximately 10⁻³ Pa by introduction of some inert gas after a prior arrival at a pressure of approximately 10⁻³ Pa or lower, a cold trap is built in for adsorbing gas which is contained in a sample and released therefrom, and quick-cooling gas circulating equipment is also built in for attaining a quick cooling from a higher temperature after completion of the heating process to room temperature in a state that the preheating tank is kept in a temperature range from room temperature to a temperature below 1000° C.

The main heating tank is preferably in a range from approximately 1200° C. to 2300° C. and more preferably in a range from approximately 1400° C. to 2300° C. where, for example, single crystal silicon carbide is subjected to heat treatment according to the liquid phase epitaxial method.

As explained so far, the heat treatment equipment according to the present embodiment is able to keep a high-purity atmosphere inside the main heating tank at an optimal treatment temperature and also maintain optimal treatment conditions by dividing the tank into a main heating tank and a preheating tank to clearly demarcate work assignments of each tank.

In this instance, the preheating tank is to heat a sample to a temperature exceeding approximately 800° C. at a pressure of 10⁻³ Pa or lower, thereby removing outgas and increasing temperatures to an intermediate stage. Further, the main heating tank is for heating a sample in a short time to an optimal treatment temperature or to a temperature exceeding, for example, 1800° C. at a pressure of 10⁻³ Pa or lower.

A sample can be transported quickly within one minute between the main heating tank and the preheating tank by an air-driven linear movement or a motor-driven circular movement. Further, where a new gas is released inside the main heating tank, a vacuum pump having a sufficient capacity of discharging air exclusively for the tank is provided to rapidly remove contaminated gas out of the tank. Further, an auxiliary physical adsorption-removing mechanism such as cold trap is also provided inside the preheating tank, thereby making it possible to completely prevent deterioration of a heater, a reflector and others disposed inside the main heating tank.

Conventional heat treatment equipment has defects that a soaking region is narrow and temperature control is difficult in the soaking region or maintaining a high temperature region free of impurity gas is difficult where heating is performed in a high vacuum (at a pressure of 10⁻³ Pa or lower) or in some rarefied gas atmosphere. According to the present embodiment, after adsorbed gas and contained gas such as hydrogen released in a large quantity from a sample at an initial stage of heating are sequentially heated for removal (from room temperature to 800° C.) in a preheating tank, they are immediately transported to the main heating tank in a high-purity treatment atmosphere. Where a sample is optimally heated at high temperatures from approximately 1200° C. to 2600° C., the main heating tank is in advance heated in a range from approximately 800° C. to 2600° C., so that a quick and uniform heating can be attained, which is not realized by a conventional method. Further, in conventional heat treatment equipment, after heat treatment, it takes a long time to cool a sample down to working temperatures close to room temperature. The present equipment is, however, able to quickly cool a sample by installing a gas cooling equipment inside the preheating tank.

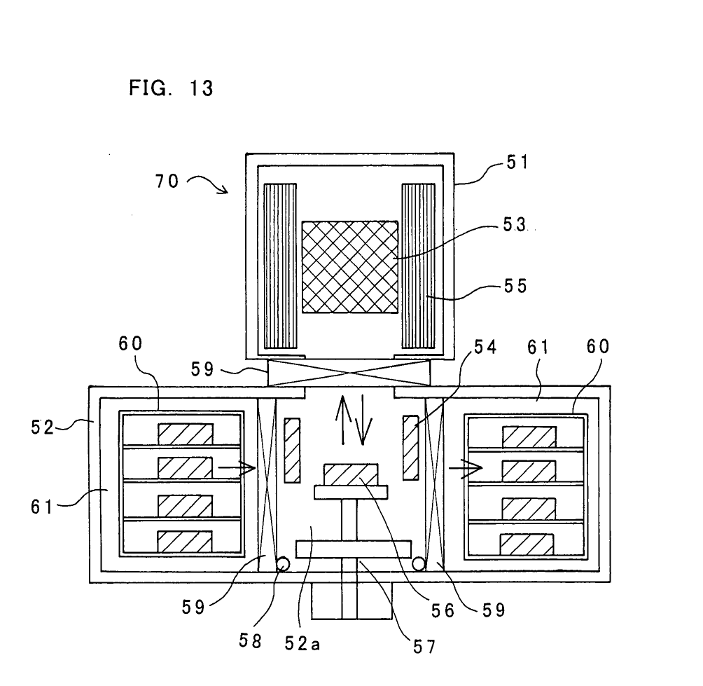

FIG. 13 shows a still another embodiment of the heat treatment equipment according to the present invention. In the present embodiment, the heat treatment equipment is provided with a high temperature heating furnace 70. As shown in FIG. 13, the preheating tank 52 of the present embodiment is provided with a halogen lamp or a rod heater 54, thereby giving a lamp-type or a rod heater-type heating furnace, by which heating can be performed quickly to the prescribed temperature in a range from approximately 800° C. to 1800° C.

Cassettes 60 for loading plural samples are placed on both sides of the preheating chamber 52, and a sample before treatment is placed on one side and that after treatment is placed on the other side. A loading and unloading tank 61 in which cassettes are loaded is separated from the preheating chamber 52a by a vacuum valve 59. The main heating tank 51 is constituted with a heater 53 made of a refractory metal, for example, a mesh-type heater made of W, and a metal reflector 55 made of a refractory metal.

In the high temperature heating furnace 70, the sample 56 is placed from the cassette 60 in which plural untreated samples are loaded to a jig and the elevating table 57 and heated in advance in a preheating tank 52 to a temperature exceeding approximately 800° C. Further, the main heating tank is also in advance heated to a prescribed temperature in a range from approximately 800° C. to 2600° C. Upon completion of pressure adjustment between the preheating chamber 52 and the main heating tank 51, the vacuum valve 59 provided between the preheating tank 52 and the main heating tank 51 is opened to transport the sample 56, jig and elevating table 57, and the temporarily heated sample 56 is heated at a prescribed temperature in q range from approximately 800° C. to 2600° C. in the main heating tank 51. In the present embodiment, heat treatment is performed at approximately 2000° C.

After completion of the treatment in the main heating tank 51, the jig and elevating table 57 are lowered to close the vacuum valve 59 between the preheating tank 52 and the main heating tank 1. Then, the sample is transferred to the cassette 60 which receives the sample that has been heat-treated. It is apparent that repetition of this procedure enables to realize a higher productivity in a shorter time than the treatment by a conventional batch-type furnace.

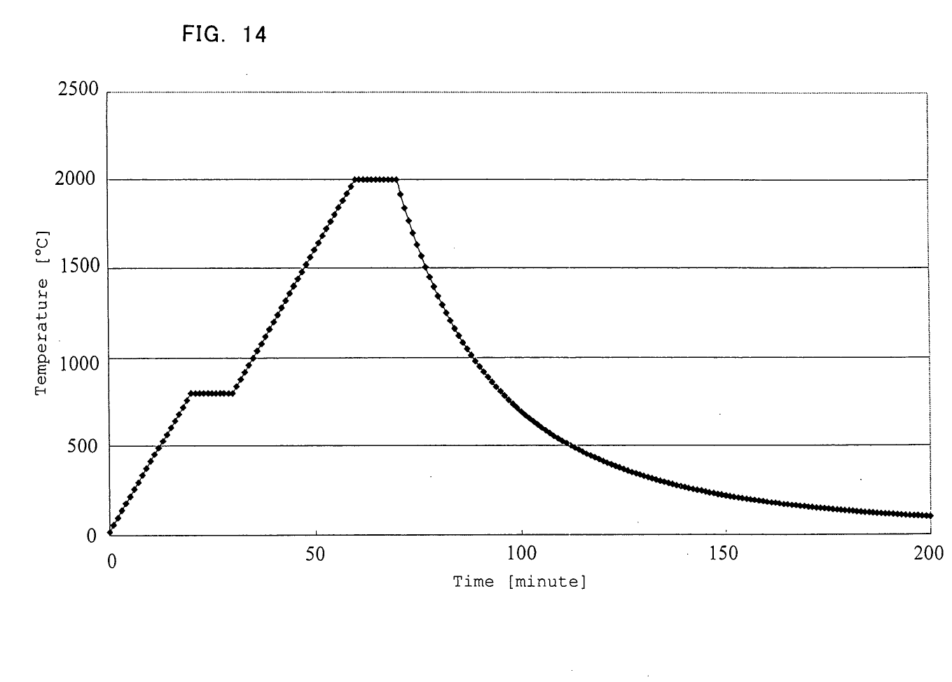

FIG. 14 shows an example of the heating temperature characteristics in this instance.

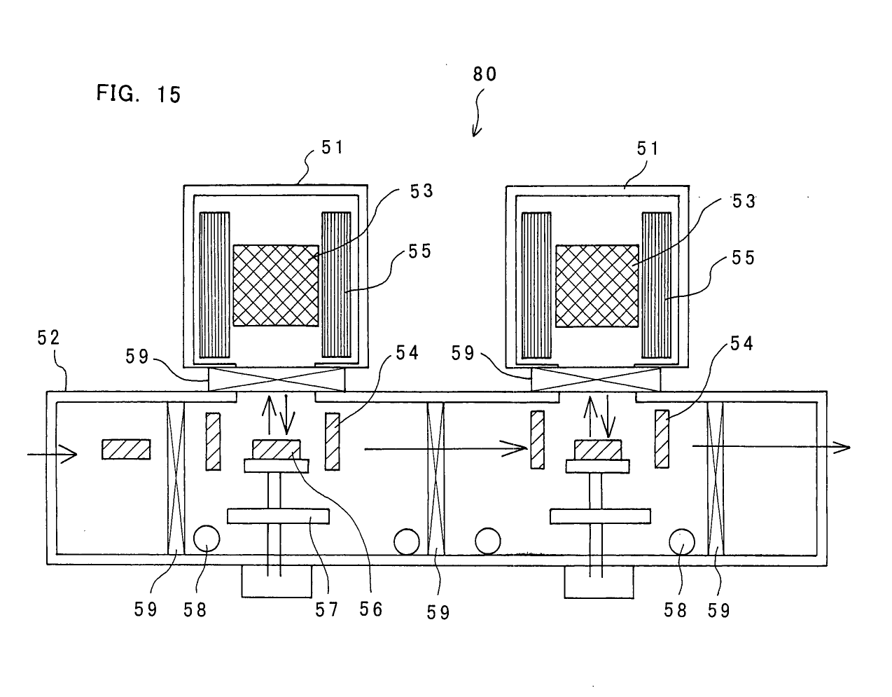

FIG. 15 shows further still another embodiment of the heat treatment equipment according to the present invention. The heat treatment equipment of the present embodiment is provided with a high temperature heating furnace 80. The high temperature heating furnace 80 is a continuous heating furnace in which a preheating tank 52 is provided with a plurality of main heating tanks 51 and the preheating tank 52 is divided by a vacuum valve 59 so as to correspond to each main heating tank 51. Such a structure makes it possible that the main heating tanks 51 are individually set at a different temperature, each of the main heating tanks 51 is allocated to each process for heat treatment to give continuously a different heat history to the sample 56. Further, this procedure is particularly excellent in productivity, as compared with a batch-type treatment.

The heat treatment equipment explained in all the above embodiments shall not be restricted to the heat treatment method carried out for subjecting single crystal SiC to the liquid phase epitaxial growth.

Taking advantage of the feature of heating a substance in a short time to a prescribed temperature in a range from approximately 800° C. to 2600° C., preferably from 1200° C. to 2300° C., the present equipment is able to provide heating to a high temperature in a short time to crystallize a part to which the ion is infused assuredly and effectively, for example, after infusion of the ion to the surface of a semiconductor substrate. Further, the heat treatment equipment according to the present embodiment is small in size and relatively simple in structure, and can be easily connected to other equipment such as ion infusion equipment.

When a high-speed heating is performed by a conventional method, special elements such as a laser, plasma and others are used. However, the heat treatment equipment according to the present embodiment is not only simple in structure but also can be connected to other equipment such as electron microscopes and ion infusion equipment. Thus, the present equipment may create new materials which have not been available by a conventional method.

The present invention has been described in the above preferable embodiments but shall not be restricted thereto. It is to be expressly understood that various embodiments are additionally available without departing from the sprit and scope of the present invention.

What is claimed is:

1. A heat treatment method by using heat treatment equipment comprising a heat chamber for heating a substance to be treated in a short time at temperatures from approximately 1200° C. to 2300° C., an anterior chamber connected to the heat chamber and equipped with a transportation means for transporting the substance to be treated to the heat chamber, and a preheating chamber connected to the anterior chamber for heating the substance to be treated to a prescribed temperature,
the heat treatment method, wherein after the substance to be treated is heated in advance to a temperature exceeding approximately 800° C. in the preheating chamber kept in a vacuum at a pressure of approximately 10⁻² Pa or lower, preferably approximately 10⁻⁵ Pa or lower, the substance is transported to the heat chamber, which is heated in advance to a prescribed temperature in a range from approximately 1200° C. to 2300° C., in a vacuum at a pressure of approximately 10⁻² Pa or lower, preferably approximately 10⁻⁵ Pa or lower or in a rarefied gas atmosphere to which inert gas is introduced after a prior arrival at a vacuum at a pressure of approximately 10⁻² Pa or lower, preferably approximately 10⁻⁵ Pa or lower, thereby heating the substance to be treated in a short time to a prescribed temperature in a range from approximately 1200° C. to 2300° C.

2. A heat treatment method used in the liquid phase epitaxial method for growing single crystal silicon carbide, wherein a monocrystal silicon carbide substrate as a seed crystal and a polycrystal silicon carbide substrate are piled up, placed inside a closed container and subjected to high-temperature heat treatment, by which a very thin metallic silicon melt layer is interposed between the monocrystal silicon carbide substrate and the polycrystal silicon carbide substrate during the heat treatment, and single crystal silicon carbide is liquid-phase-epitaxially grown on the monocrystal silicon carbide substrate,
the heat treatment method used in the liquid phase epitaxial method for producing single crystal silicon carbide, wherein the closed container is in advance heated to a temperature exceeding approximately 800° C. in an preheating chamber kept at a pressure of approximately 10⁻² Pa or lower, and the closed container is reduced in pressure to approximately 10⁻⁵ Pa or lower, the closed container is transported and placed in the heat chamber, which is in advance heated to a prescribed temperature in a range from approximately 1400° C. to 2300° C., in a vacuum at a pressure of approximately 10⁻² Pa or lower, preferably at a pressure of 10⁻⁵ Pa or lower or in a rarefied gas atmosphere to which inert gas is introduced after a prior arrival at a pressure of 10⁻⁵ Pa or lower, by which the monocrystal silicon carbide substrate and the polycrystal silicon carbide substrate are heated in a short time to a prescribed temperature in a range from approximately 1400° C. to 2300° C. to produce single crystal silicon carbide which is free of fine grain boundaries and approximately 1/cm² or lower in density of micropipe defects on the surface.

3. The heat treatment method used in the liquid phase epitaxial method for growing single crystal silicon carbide according to claim 2, wherein temperature difference is not provided in an axial direction of the closed container but temperature gradient is provided in a plane direction of the closed container and the temperature gradient is arbitrarily controlled, thereby preventing formation of fine grain boundaries, when the closed container is transported to the heat chamber.

4. The heat treatment method used in the liquid phase epitaxial method for growing single crystal silicon carbide according to claim 2, wherein the closed container is made of either tantalum or tantalum carbide.

5. The heat treatment method used in the liquid phase epitaxial method for growing single crystal silicon carbide according to claim 2, wherein the closed container is formed with an upper container cup wall and a lower container cup wall, and the pressure inside the closed container is controlled so as to be higher than that inside the heat chamber to such an extent that silicon vapor leaks from the fitting part of the upper container cup wall with the lower container cup wall, thereby preventing inclusion of impurities into the closed container.

6. The heat treatment method used in the liquid phase epitaxial method for growing single crystal silicon carbide according to claim 2, wherein a contaminant removing mechanism is provided inside the heat chamber for physically adsorbing silicon vapor leaking from the closed container.

7. The heat treatment method used in the liquid phase epitaxial method for growing single crystal silicon carbide according to claim 2, wherein the surface of the single crystal silicon carbide has an atomic order step as a minimum unit of a three-molecular layer and a broad terrace, and a width of the terrace is approximately 10 μm or more.

8. The heat treatment method used in the liquid phase epitaxial method for growing single crystal silicon carbide according to claim 7, wherein the surface is (0001) Si plane.

9. The heat treatment method used in the liquid phase epitaxial method for growing single crystal silicon carbide according to claim 2, wherein the very thin metallic silicon melt layer is approximately 50 μm or lower in thickness.

10. Heat treatment equipment comprising a heat chamber wherein a substance to be treated is heated in a short time in a range from approximately 1200° C. to 2300° C. in a vacuum at a pressure of approximately 10⁻² Pa or lower, preferably at approximately 10⁻⁵ Pa or lower or in a rarefied gas atmosphere to which inert gas is introduced after a prior arrival at vacuum at a pressure of approximately 10⁻² Pa or lower preferably at a pressure of approximately 10⁻⁵ Pa or lower,
an anterior chamber connected to the heat chamber and equipped with a transportation means for transporting the substance to be treated to the heat chamber,
and a preheating chamber connected to the anterior chamber and heating in advance the substance to be treated to a temperature exceeding approximately 800° C. in a vacuum at a pressure of approximately 10⁻² Pa or lower or preferably approximately 10⁻⁵ Pa or lower.

11. The heat treatment equipment according to claim 10, wherein the heating means of the preheating chamber is a lamp-type heating means.

12. Heat treatment equipment comprising a high-temperature heating furnace wherein the inside of a vacuum high-temperature furnace is composed of two or more divided tanks, the inside of each of these plurality of tanks is constituted with a main heating tank and a preheating tank, the preheating tank is heated from a room temperature to approximately 800° C. for degassing the gas mainly adsorbed to a sample and the gas contained inside the sample, after completion of the degassing, the sample is smoothly transported to the main heating tank which is in advance discharged of air by heating and vacuum treatment and kept clean and at high temperatures, the main heating tank is constantly heated to a prescribed high temperature in a range from approximately 800° C. to 2600° C. constantly at a pressure of approximately 10⁻³ Pa or lower or in a rarefied gas atmosphere at any given pressure from ambient pressure to approximately 10⁻³ Pa by introduction of some inert gas after a prior arrival at approximately 10⁻³ Pa or lower pressure, the preheating tank has the function of discharging air from ambient pressure for supplying and removing a sample to a pressure level which is the same as that attained by the main heating tank necessary for transporting the sample to or from the main heating tank, and after a preheating of the sample from room temperature to approximately 800° C., a quick transportation to the main heating tank enables to attain a high-temperature and high-purity atmosphere at a prescribed temperature in a range from approximately 800° C. to 2600° C. which is an optimal temperature for treating the sample.

13. The heat treating equipment according to claim 12 comprising a high temperature heating furnace having a high purity atmosphere in which the main heating tank is set to conduct heat treatment in the temperature range from approximately 1200° C. to 2600° C., wherein a heating part of the high temperature heating furnace is made of a refractory metal such as W or Ta, a component used at thermal reflectance and heat insulating regions enclosing high temperature regions is provided with a composite structure made of a refractory metal material selected from W, Ta or Mo, the component made of a refractory metal at the heat-blocking region is provided on the surface with an infrared-ray reflecting film having any given wavelength region ranging from approximately 0.4 μm to 3.5 μm which reflects an emission wavelength region of the heating part.

14. The heat treatment equipment according to claim 12 comprising a high temperature heating furnace wherein a heat insulation region constituted with refractory metal plates enclosing the heater part of the main heating tank is provided with a composite structure composed of a heat insulation layer and a heat-ray reflective layer, each layer has the function of insulating heat and reflecting heat rays, the surface of the refractory metal plates constituting the heat insulation region is coated with highly heat-resistant metal carbides such as WC, TaC, MoC, ZrC, HfC and BN or with metal nitrides solely or in combination, thereby providing the function of preventing deterioration or deformation of refractory metals, the surface of the refractory metal as a heat-ray reflective layer is coated with an infrared ray reflecting film made of Au or others, thereby providing the function of reflecting at a high efficiency the region of any given emission wavelength from approximately 0.4 to 3.5 μm.

15. Heat treatment equipment comprising a high-speed and high-temperature heating furnace, wherein a vacuum high-temperature furnace is divided into two tanks or a main heating tank and a preheating tank for rapid heating of a sample, and at the same time for keeping a high-purity atmosphere, the inside of each tank is provided with an individually independent vacuum discharge system or an individually independent gas introduction system and capable of keeping an ambient pressure atmosphere, and the main heating tank and the preheating tank are mutually kept integrated or divided by opening or closing a cut-off valve,
the heat treatment equipment having a high temperature heating furnace, wherein the main heating tank is kept at high temperatures in a range from approximately 800° C. to 2600° C. constantly at a pressure of approximately 10⁻³ Pa or lower during a regular use or in a rarefied gas atmosphere of any given pressure from ambient pressure to approximately 10⁻³ Pa by introduction of some inert gas after a prior arrival at a pressure of approximately 10⁻³ Pa or lower, a cold trap is built in for adsorbing gas which is contained in a sample and released therefrom, and quick-cooling gas circulating equipment is also built in for attaining a quick cooling from a higher temperature after completion of the heating process to room temperature in a state that the preheating tank is kept in the temperature range from room temperature to the temperature below 1000° C.

16. The heat treatment equipment according to claim 15 comprising a high temperature heating furnace, wherein a heating source of the preheating tank is a halogen lamp or an Xe lamp equipped with a reflecting mirror for concentrating near-infrared rays on a sample or an infrared heating lamp equipped with an infrared ray generating film on the outer surface of the lamp tare for a rapid heating in a short time.

17. The heat treatment equipment according to claim 15, wherein the heating part of the main heating tank is provided with a high-temperature heating furnace constituted with a tubular main heater and a flat auxiliary heater, each of which is made of a refractory metal.
